(19) United States
(12) Patent Application Publication
(10) Pub. No.: US 2013/0161616 A1
(43) Pub. Date: Jun. 27, 2013

(54) Substrate for Chip on Film

(71) Applicants: Chir-Hsiang Hsu, Hsinchu City (TW); Chin-Hung Hsu, Taoyuan County (TW); Chih-Chiang Chan, Hsinchu City (TW); Hai-Lun Chen, Hsinchu City (TW)

(72) Inventors: Chir-Hsiang Hsu, Hsinchu City (TW); Chin-Hung Hsu, Taoyuan County (TW); Chih-Chiang Chan, Hsinchu City (TW); Hai-Lun Chen, Hsinchu City (TW)

(21) Appl. No.: 13/439,840

(22) Filed: Apr. 4, 2012

(30) Foreign Application Priority Data
Dec. 26, 2011 (TW) 100148560

(51) Int. Cl. H01L 23/58

(52) U.S. Cl. 257/48; 257/E23.002

(57) ABSTRACT

The present invention discloses a substrate including a flexible film, a plurality of sprocket holes disposed along a first direction on two sides of the flexible film, and a plurality of first chip zones disposed along the first direction on the flexible film, of which each first chip zone includes at least a testing module, an input module, a chip and an output module disposed along a second direction, where the first direction is orthogonal to the second direction.

### BACKGROUND OF THE INVENTION

1. Field of the Invention

The present invention relates to a substrate for Chip on Film (COF), and more particularly, to a substrate which dramatically lowers production costs for COF.

2. Description of the Prior Art

A liquid crystal display (LCD) has advantages of light weight, low power consumption, low radiation contamination, etc., and is widely used in various information products, such as computer systems, cell phones, personal digital assistants (PDAs), etc. Generally, driving chips of the LCD are installed onto a display panel via Chip on Film (COF), Tape Carrier Package (TCP), and Chip on Glass (COG) to reduce areas of the driving chips. In comparison with TCP or COG, COF provides direct coupling to a file/tape rather than forming component holes for connection, which provides better pin-connection strength and finer pin pitch. Additionally, COF utilizes two-layer flexible materials without glue for better flexibility and thinner structure. For composing component connections, COF also provides more convenient integration for active units, passive units or driving chips.

Please refer to FIG. 1, which illustrates a schematic diagram of a conventional substrate 10 for COF. Hereinafter, the substrate 10 is demonstrated with 48 mm width. As shown in FIG. 1, the substrate 10 located on the XY-plane includes a plurality of sprocket holes 100 and a plurality of chip disposing zones 102. The sprocket holes 100 are disposed along the Y-axis direction on two sides of the substrate 10. Each of the chip disposing zones 102 is disposed at a central zone of the substrate 10 surrounded at left or right by the sprocket holes 100. Each of the chip disposing zones 102 includes a chip 1020, an input module 1022, an output module 1024 and at least a testing module 1026. Also, each of the chip disposing zones 102 is parallel to each other along the Y-axis direction, and the chip 1020, the input module 1022, the output module 1024 and the testing module 1026 are parallel to each other along the Y-axis direction. After subtracting widths of the sprocket holes 100 on two sides of the substrate 10, the chip disposing zones 102 only have width of 41 mm in the X-axis direction, which corresponds to having 1100 pins of the output module 1024 and a pin pitch of 37 micrometers. However, in pursuit of image quality, it is inevitable that pin number will increase, such as to 1440 pins. In this situation, the pin pitch has to be reduced to comply with the limited area of the chip disposing zone to accommodate product costs, which causes weakening of the pin-connection strength as a consequence of the finer pin pitch. A better connection between the pin and the display panel is required, and nevertheless, adds extra production costs.

Therefore, it has become an important issue to provide an effective arrangement of the chip disposing zone to accommodate the increasing pin number for better image quality without sacrificing the pin pitch within the limited chip disposing zone.

### SUMMARY OF THE INVENTION

It is therefore an objective of the invention to provide a substrate for COF.

The present invention discloses a substrate for COF comprises a flexible film, a plurality of sprocket holes disposed along a first direction on two sides of the flexible film; and a plurality of first chip disposing zones disposed along the first direction on the flexible film, each first chip disposing zone comprising at least a testing module, an input module, a chip and an output module disposed along a second direction; wherein the first direction is perpendicular to the second direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of a conventional substrate for COF.

FIG. 2 illustrates a schematic diagram of a substrate for COF according to an embodiment of the invention.

FIG. 3 illustrates a schematic diagram of another substrate for COF according to an embodiment of the invention.

FIG. 4 illustrates a schematic diagram of a modification of the substrate shown in FIG. 3 according to an embodiment of the invention.

FIG. 5 illustrates a schematic diagram of a reserving method of COF according to an embodiment of the invention.

### DETAILED DESCRIPTION

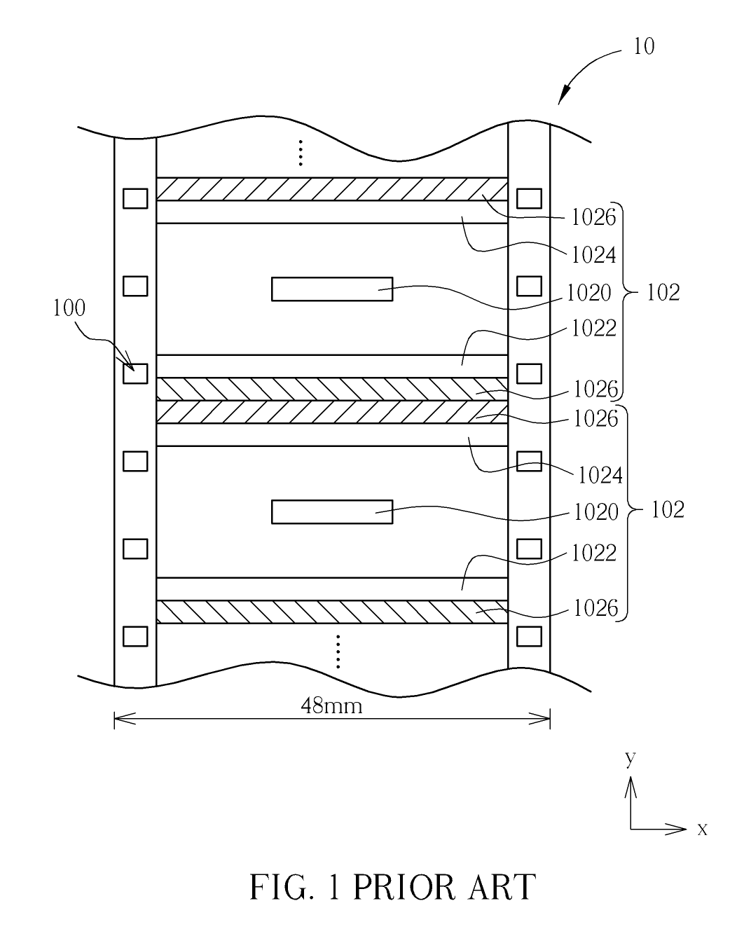

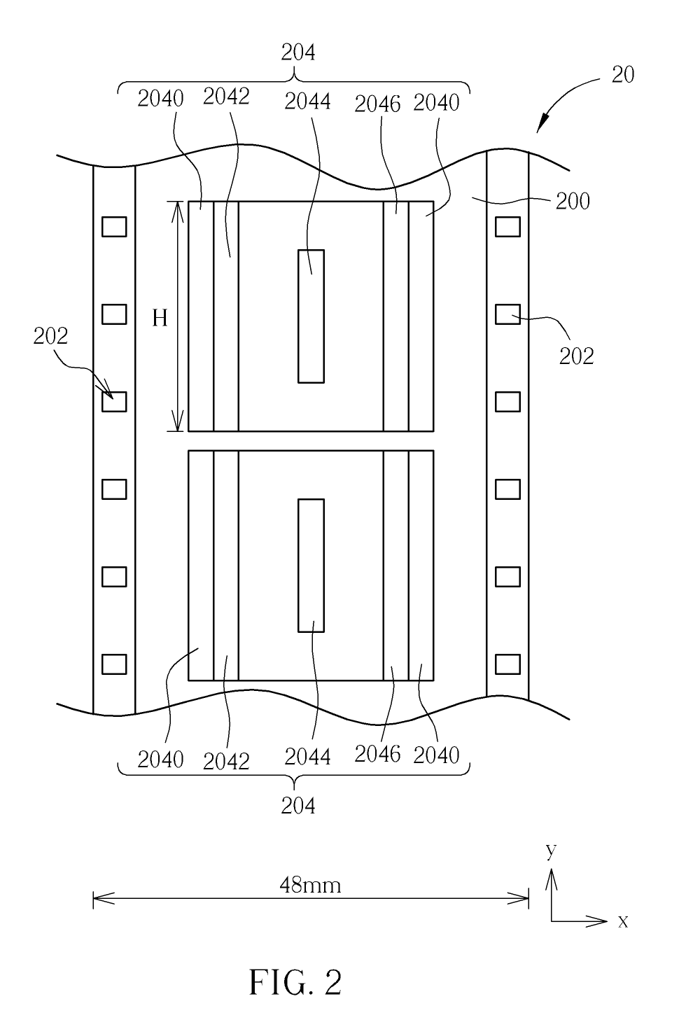

Please refer to FIG. 2, which illustrates a schematic diagram of a substrate 20 for COF according to an embodiment of the invention. In comparison with the substrate 10 in FIG. 1, the substrate 20 has similar elements with a different arrangement of the elements, which maintains the original pin pitch and increases the pin number within the same area of the chip disposing zone. The same process machines can still be utilized with a few step modifications/changes to achieve the same COF technique.

As shown in FIG. 2, the substrate 20 extends along the Y-axis direction in the XY-plane, and a limited length of the substrate 20 is depicted hereinafter for simplicity. To those skilled in the art, the XY-plane includes the X-axis direction perpendicular to the Y-axis direction for coordinate positioning. In detail, the substrate 20 includes a flexible film 200, a plurality of sprocket holes 202 and a plurality of first chip disposing zones 204. The flexible film 200 is a flexible printed circuit as a chip carrier, and preferably, includes two-layer structures having one polyimide layer and another copper layer. The two-layer structures are formed via casting, lamination, sputtering/plating, or any similar adhering/attachment methods to form features of flexibility, and material sizes or production processes thereof can be adjusted according to different purposes, which are not the emphasis of the invention and can be simplified hereinafter. The sprocket holes 202 are parallel in the Y-axis direction, and formed on two sides of the flexible film 200 with the same interval relative to each other, which provides a convenient process for reel-to-reel manufacture.

Additionally, as shown in FIG. 2, the first chip disposing zones 204 are formed on the flexible film 200 along the Y-axis direction sequentially. Each of the first chip disposing zones 204 includes two testing modules 2040, an input module 2042, a chip 2044 and an output module 2046 parallel with the X-axis direction, which means the first chip disposing zones 204 can be cut as a plurality of rectangular zones parallel to each other, wherein the rectangular zones are the testing modules 2040, the input module 2042, the chip 2044 and the output module 2046. Precise arrangement of the rectangular zones is only for demonstration hereinafter, and can be adaptively adjusted according to different purposes. The input module 2042 provides the inner lead bonding (ILB) to a printed circuit (not shown in the figure) of the display panel. The output module 2046 provides the outer lead bonding (OLB) to a glass base (not shown in the figure) of the display panel. The testing module 2040 provides a plurality of pins electrically connected to the chip 2044 to check whether or not the chip 2044 operates functionally. The chip 2044 is installed onto the flexible film 200 by attachment methods, such as eutectic bonding, anisotropic conductive film, non-conducting glue, or a combination thereof. Then, a plurality of pins of the chip 2044 are formed via gold bumping or solder bumping, and electrically connected to the testing module 2040, the input module 2042 and the output module 2046 via lamination. If the chip 2044 is verified to operate functionally, the plurality of first chip disposing zones 204 are punched to divide into a single first chip disposing zone 204, which includes the input module 2042, the chip 2044 and the output module 2046 to form the first chip module (not shown in the figure) as the final product of the COF process.

In comparison with the prior art, the first chip disposing zone 204 makes the pin number of the input module 2042 and the output module 2046 not limited by the width of the substrate 20, such as 35 mm, 48 mm or 70 mm. Instead, a first chip disposing zone height H of the substrate 20 can arbitrarily extend along the Y-axis direction according to different requirements, and comply with increasing pin number to form an effective arrangement of the chip disposing zones.

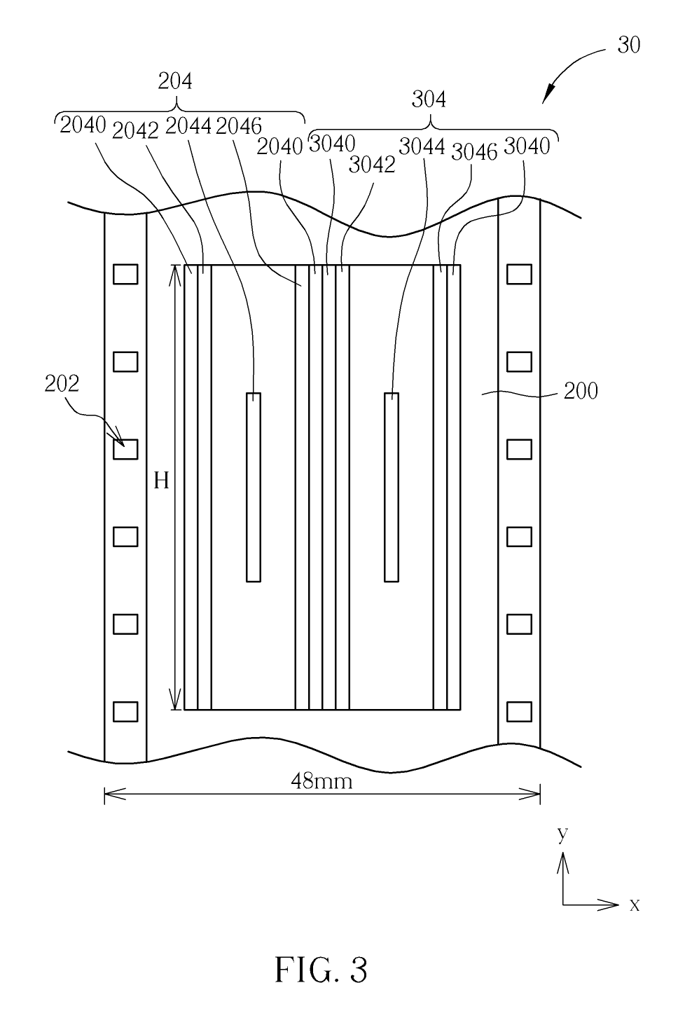

Please refer to FIG. 3, which illustrates a schematic diagram of another substrate 30 for COF according to an embodiment of the invention. In comparison with the substrate 20 in FIG. 2, the substrate 30 includes the same elements. However, the substrate 30 further provides a plurality of second chip disposing zones 304, and only one of the plurality of second chip disposing zones 304 is shown in FIG. 3. In detail, the second chip disposing zone 304 has elements and structure identical to the first chip disposing zones 204, which means the second chip disposing zone 304 includes at least one testing module 3040, an input module 3042, a chip 3044 and an output module 3046. The second chip disposing zone 304 is installed on one side of the first chip disposing zone 204, and the second chip disposing zone 304 is parallel to the first chip disposing zone 204 along the X-axis direction via the testing modules 2040, 3040, which means the first chip disposing zone 204 and the second chip disposing zone 304 of the substrate 30 can be seen in sequence along the X-axis direction. Hereinafter, the arrangement number or the sequential order of the first chip disposing zone 204 and the second chip disposing zone 304 are only for demonstration.

In application, the substrate 30 is also punched in a similar way to the substrate 20 to maintain the input module 2042 (3042), the chip 2044 (3044) and the output module 2046 (3046), so as to punch the first chip disposing zone 204 (the second chip disposing zone 304) to divide into a single first chip disposing zone 204 (single second chip disposing zone 304) and form the first chip module (the second chip module). In other words, the user can put a plurality of chip disposing zones within the same first chip disposing height H according to different requirements, to reduce production costs and form another effective arrangement of the chip disposing zone. Hereinafter, the arrangement number of the chip disposing zone is only for demonstration, and is not limiting on the scope of the invention.

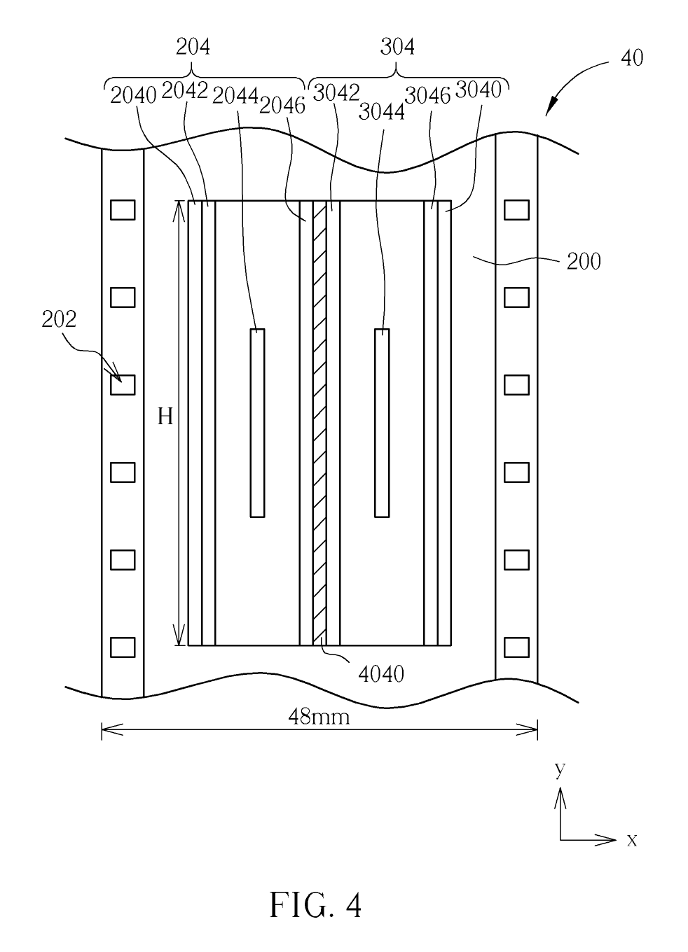

Please refer to FIG. 4, which illustrates a schematic diagram of a modification of the substrate 30 shown in FIG. 3 according to an embodiment of the invention. As shown in FIG. 4, the substrate 40 further integrates the testing module 2040 of the first chip disposing zone 204 with the testing module 3040 of the second chip disposing zone 304 shown in FIG. 3, and rotates the second chip disposing zone 304 shown in FIG. 3 with an angle of 180 degrees to form a mirroring arrangement, i.e. composing elements of the second chip disposing zone 304 along the X-axis direction are formed in reverse to have a sharing testing module 4040. The sharing testing module 4040 has the features of the testing modules 2040, 3040, which includes adjusting its area according to different requirements, verifying whether or not the chip 2044(3044) operates functionally, and increasing utilization of the limited area of the substrate 40, and provides another effective arrangement of the chip disposing zone. In this situation, the substrate 40 is punched through the sharing testing module 4040 to divide the first chip disposing zone 204 and the second chip disposing zone 304 into the single first chip module and the single second chip module for independent operation respectively. Another effective arrangement of the chip disposing zone is provided, and the production costs can be saved for disposing a plurality of chip disposing zones within the same first chip disposing zone height H.

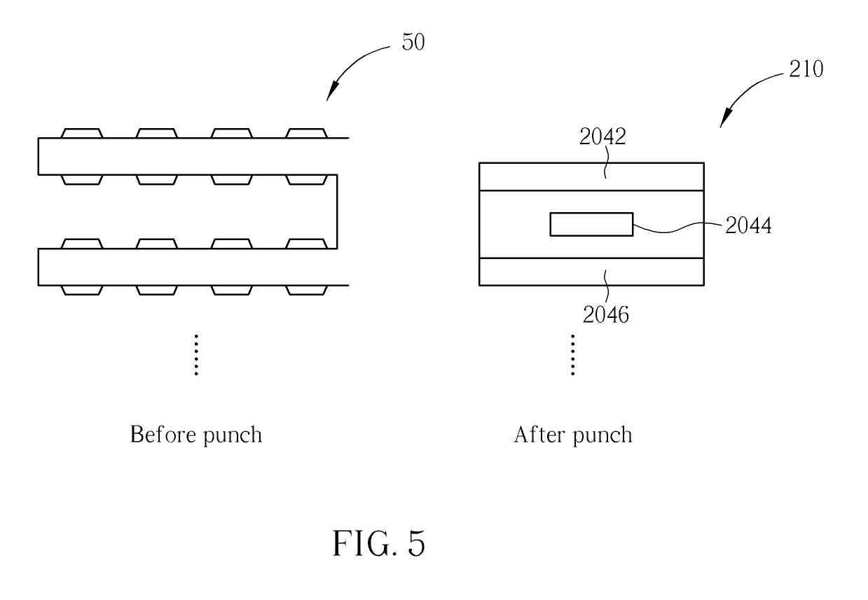

Noticeably, the invention utilizes the plurality of sprocket holes to process the reel-to-reel manufacture. The substrates 20, 30, 40 can be reserved in an S-stack shape before being punched. FIG. 5 corresponds to a reserving method of COF according to the embodiment of the invention. After the reserved substrate 50 is punched, it generates the plurality of first chip modules 210, each of which still includes the input module 2042, the chip 2044 and the output module 2046.

Certainly, arrangement of the chip disposing zone of the invention is only for demonstration. According to different requirements on the practical width of the flexible film, the user can adjust the sequential arrangement of the chip disposing zone to maintain the testing module, the input module, the chip and the output module being parallel to each other along the X-axis direction. Further, punching with different parallel arrangement-number or method can be chosen to prevent sacrificing the pin pitch and to increase the pin number within the limited area of the chip disposing zone, which is the scope of the invention.

In summary, different arrangement of chip disposing zones of the invention is provided. In comparison with the prior art, a plurality of elements instead of a single element are included in the chip disposing zone along the X-axis direction according to the embodiment of the invention. Positioning of a plurality of chip disposing zones can be adaptively adjusted. Preferably, when the plurality of chip disposing zones neighbor each other, they share some sharing composing elements, such as a sharing testing module, and regard the sharing composing elements as a symmetrical axis to form an identical structure arrangement or mirroring arrangement, to avoid sacrificing the pin pitch and to increase the pin number within a limited area of the chip disposing zone, so as to elevate utilized area efficiency of the chip disposing zone. Further, the user can save the production costs and comply with high image quality of display panels.

Those skilled in the art will readily observe that numerous modifications and alterations of the device and method may be made while retaining the teachings of the invention. Accordingly, the above disclosure should be construed as limited only by the metes and bounds of the appended claims.

1. A substrate comprises:
a flexible film;
a plurality of sprocket holes disposed along a first direction on two sides of the flexible film; and
a plurality of first chip disposing zones disposed along the first direction on the flexible film, each first chip disposing zone comprising at least a testing module, an input module, a chip and an output module disposed along a second direction;
wherein the first direction is perpendicular to the second direction, and more than one element number of each first chip disposing zone is obtained along the second direction.

2. The substrate of claim 1, further comprising a plurality of second chip disposing zones disposed along the first direction on the flexible film and connected to one side of the plurality of first chip disposing zones along the second direction, each second chip disposing zone comprising at least a testing module, an input module, a chip and an output module disposed along the second direction, wherein one testing module of each first chip disposing zone is connected to one testing module of each second chip disposing zone.

3. The substrate of claim 2, wherein the testing module of each first chip disposing zone connected to the testing module of each second chip disposing zone is integrated with the connected testing module of each second chip disposing zone to form a sharing testing module.

4. The substrate of claim 1, wherein the testing module, the input module and the output module are electrically coupled to the chip.

5. The substrate of claim 4, wherein the testing module checks whether or not the chip operates functionally.

6. The substrate of claim 4, wherein the input module and the output module are electrically coupled to a display device to drive the chip.

7. The substrate of claim 1, wherein the flexible film comprises structures of two layers, one of which is a polyimide layer and the other is a copper layer.

8. The substrate of claim 1, wherein the plurality of first chip disposing zones are punched to divide into a single first chip module for independent operation.

9. The substrate of claim 2, wherein the plurality of second chip disposing zones are punched to divide into a single second chip module for independent operation.

10. A substrate comprises:
a flexible film;
a plurality of sprocket holes disposed along a first direction on two sides of the flexible film;
a plurality of first chip disposing zones disposed along the first direction on the flexible film, each first chip disposing zone comprising at least a testing module, an input module, a chip and an output module disposed along a second direction; and
a plurality of second chip disposing zones disposed along the first direction on the flexible film and connected to one side of the plurality of first chip disposing zones along the second direction, each second chip disposing zone comprising at least a testing module, an input module, a chip and an output module disposed along the second direction, wherein one testing module of each first chip disposing zone is connected to one testing module of each second chip disposing zone;
wherein the first direction is perpendicular to the second direction.
